(19) United States
(12) Patent Application Publication
(10) Pub. No.: US 2010/0167190 A1
(43) Pub. Date: Jul. 1, 2010

(54) PATTERN-CORRECTION SUPPORTING METHOD, METHOD OF MANUFACTURING SEMICONDUCTOR DEVICE AND PATTERN-CORRECTION SUPPORTING PROGRAM

(76) Inventors: Kazuhiro TAKAHATA, Kanagawa (JP); Shoji MIMOTOGI, Kanagawa (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/612,163

(22) Filed: Nov. 4, 2009

(30) Foreign Application Priority Data
Dec. 27, 2008 (JP) 2008-335564

(51) Int. Cl. G03F 7/20; G06K 9/00

(52) U.S. Cl. 430/30; 382/145

(57) ABSTRACT

Design data corresponding to a target layout pattern is created, a layout value of the created design data is changed, optical proximity correction is applied to a layout pattern obtained from the changed design data, a pattern on wafer formed on a wafer to correspond to the layout pattern is calculated by using a photomask on which the layout pattern subjected to the optical proximity correction is formed, and the pattern on wafer and the target layout pattern before the change of the layout value are compared.

### CROSS-REFERENCE TO RELATED APPLICATIONS

This application is based upon and claims the benefit of priority from the prior Japanese Patent Application No. 2008-335564, filed on Dec. 27, 2008; the entire contents of which are incorporated herein by reference.

### BACKGROUND OF THE INVENTION

1. Field of the Invention

The present invention relates to a pattern-correction supporting method, a method of manufacturing a semiconductor device, and a pattern-correction supporting program, and, more particularly is suitably applied to a method of correcting layout values of design data before optical proximity correction (OPC) to reduce a difference between an actual pattern transferred onto a wafer and a layout pattern obtained from the design data.

2. Description of the Related Art

According to the microminiaturization of semiconductor integrated circuits in recent years, a pattern equal to or smaller than a half of the wavelength of light is formed by photolithography. In this case, errors between the dimensions of a pattern actually formed on a wafer and design values are large. Therefore, such errors are predicted by computer simulation and the optical proximity correction is applied to a mask pattern to bring the dimensions of the pattern actually formed on the wafer close to the design values.

Japanese Patent Application Laid-Open No. 2001-338304 discloses a method called die-to-database comparison for converting CAD data into an image format and comparing the image format with an image obtained from an inspection target die to inspect a wafer and a reticle.

However, when condition setting for a process is insufficient or when OPC accuracy is insufficient, even if the optical proximity correction is performed, it is difficult to form an actual pattern having dimensions as designed on a wafer.

### BRIEF SUMMARY OF THE INVENTION

A pattern-correction supporting method according to an embodiment of the present invention comprises: creating design data corresponding to a target layout; changing a layout value of design data corresponding to a target layout; applying optical proximity correction to the changed design data; forming patterns on a wafer with the photomask on which the layout pattern subjected to the optical proximity correction is formed; comparing the pattern on wafer and the target layout pattern before the layout value is changed.

A pattern-correction supporting method according to an embodiment of the present invention comprises: creating design data corresponding to a target layout; changing a layout value of the created design data; applying optical proximity correction to the changed design data; increasing or decreasing a mask dimension specified value of the layout pattern subjected to the optical proximity correction; forming patterns on a wafer with the photomask on which the layout pattern after the optical proximity correction with the mask dimension specified value increased or decreased is formed; comparing the pattern on wafer and the target layout pattern before the layout value is changed.

A pattern-correction supporting method according to an embodiment of the present invention comprises: preparing a first layout corresponding to a first pattern, the first pattern is being target pattern to be formed on a substrate; changing the first layout to a second layout, the second layout is corresponding to a second pattern different from the first pattern; and applying optical proximity correction to the second layout.

A method of manufacturing a semiconductor device according to an embodiment of the present invention comprises: changing a layout value of design data corresponding to a target layout; applying optical proximity correction to the changed design data; forming patterns on a wafer with the photomask on which the layout pattern subjected to the optical proximity correction is formed; comparing the pattern on wafer and the target layout pattern before the layout value is changed; extracting the changed design data, a result of the comparison of which satisfies a desired condition; and transferring, onto a semiconductor substrate, a mask pattern obtained by applying the optical proximity correction to the extracted design data.

A pattern-correction supporting program for causing a computer to execute according to an embodiment of the present invention comprises: acquiring design data corresponding to a target layout pattern; acquiring a layout value after change of the acquired design data; and comparing a pattern formed by using a photomask manufactured based on the design data after the change and an image of the target layout pattern obtained from the design data.

A pattern-correction supporting program for causing a computer to execute according to an embodiment of the present invention comprises: preparing a first layout corresponding to a first pattern, the first pattern is being target pattern to be formed on a substrate; changing the first layout to a second layout, the second layout is corresponding to a second pattern different from the first pattern; and applying optical proximity correction to the second layout.

### BRIEF DESCRIPTION OF THE DRAWINGS

FIG. 1 is a block diagram of a schematic configuration of a system to which a pattern-correction supporting method according to a first embodiment of the present invention is applied;

FIG. 2 is a flowchart of the pattern-correction supporting method according to the first embodiment;

FIG. 3 is a block diagram of the hardware configuration of a pattern-correction supporting apparatus according to the first embodiment;

FIG. 4 is a diagram of design layout patterns used for the pattern-correction supporting method according to the first embodiment, mask patterns after OPC processing, and actual patterns transferred onto a wafer;

FIG. 5 is a block diagram of the schematic configuration of a system to which a pattern-correction supporting method according to a second embodiment of the present invention is applied;

FIG. 6 is a flowchart of the pattern-correction supporting method according to the second embodiment;

FIG. 7 is a diagram of design layout patterns used for the pattern-correction supporting method according to the second embodiment, mask patterns after OPC processing, and actual patterns transferred onto a wafer;

FIG. 8 is a block diagram of the schematic configuration of a system to which a pattern-correction supporting method according to a third embodiment of the present invention is applied;

FIG. 9 is a flowchart of the pattern-correction supporting method according to the third embodiment; and

FIG. 10 is a diagram of an example of design layout patterns used for the pattern-correction supporting method according to the third embodiment, mask patterns after OPC processing, and actual patterns transferred onto a wafer.

### DETAILED DESCRIPTION OF THE INVENTION

Exemplary embodiments of the present invention are explained in detail below with reference to the accompanying drawings. The present invention is not limited by the embodiments.

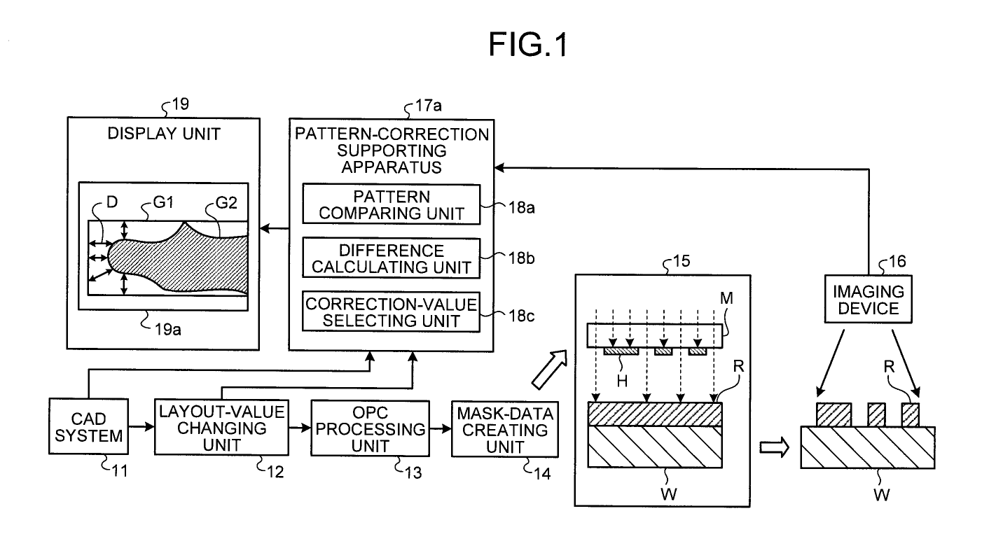

FIG. 1 is a block diagram of a schematic configuration of a system to which a pattern-correction supporting method according to a first embodiment of the present invention is applied.

In FIG. 1, a pattern-correction supporting apparatus 17a includes a pattern comparing unit 18a, a difference calculating unit 18b, and a correction-value selecting unit 18c. A CAD system 11, a layout-value changing unit 12, an imaging device 16, and a display device 19 are connected to the pattern-correction supporting apparatus 17a.

The CAD system 11 can create design data corresponding to a target layout pattern. As a data format of design data, for example, text coordinate data, GDS data, oasis data, HSS data, or image data (Tiff, Bit Map, and Jpeg) can be used. The layout-value changing unit 12 can change layout values of the design data created by the CAD system 11. Examples of the layout values of the design data include dimensions and an arrangement position of the layout pattern. The imaging device 16 can image an actual pattern formed on a wafer W as a pattern on wafer. As an image imaged by the imaging device 16, an electron microscope image and the like can be used besides an optical microscope image. The display device 19 can display information for executing pattern correction on a display screen 19a in cooperation with the pattern-correction supporting apparatus 17a.

The pattern comparing unit 18a can compare the actual pattern on the wafer W imaged by the imaging device 16 and the target layout pattern obtained from the design data created by the CAD system 11. The difference calculating unit 18b can calculate differences between the dimensions of the actual pattern on the wafer W imaged by the imaging device 16 and the target layout pattern obtained from the design data created by the CAD system 11. The correction-value selecting unit 18c can select the layout value after change to reduce the differences between the dimensions calculated by the difference calculating unit 18b.

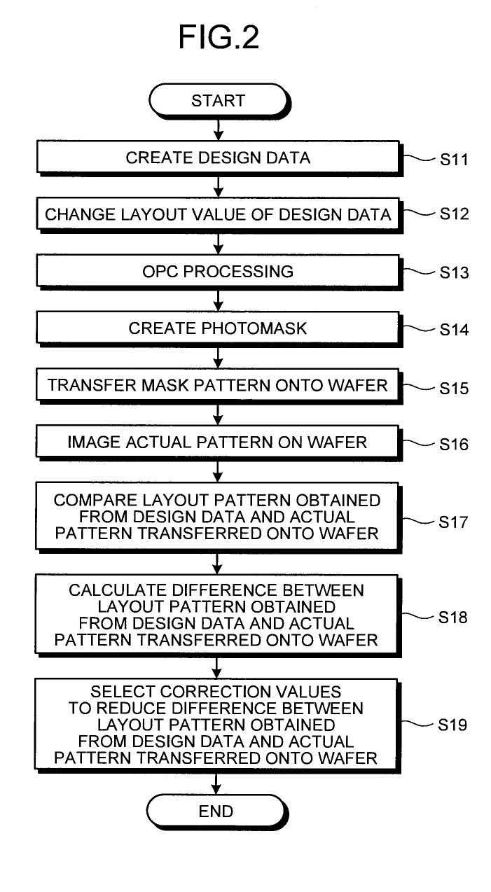

FIG. 2 is a flowchart of the pattern-correction supporting method according to the first embodiment.

In FIG. 2, the CAD system 11 creates design data corresponding to a target layout pattern (step S11) and sends the design data to the layout-value changing unit 12 and the pattern-correction supporting apparatus 17a. The layout-value changing unit 12 changes layout values of the design data created by the CAD system 11 (step S12) and sends the layout values to the OPC processing unit 13 and the pattern-correction supporting apparatus 17. The OPC processing unit 13 applies optical proximity correction to a layout pattern obtained from the design data changed by the layout-value changing unit 12 (step S13) and sends the layout pattern to the mask-data creating unit 14. The mask-data creating unit 14 creates mask data corresponding to the layout pattern subjected to the optical proximity correction by the OPC processing unit 13 (step S14). A light blocking film H is formed on a photomask M based on the mask data created by the mask-data creating unit 14.

When the photomask M on which the light blocking film H is formed and the wafer W on which a resist film R is formed are arranged on an exposing device 15, the exposing device 15 exposes the resist film R via the photomask M. Development of the resist film R exposed by the exposing device 15 is performed, whereby the resist film R is patterned (step S15).

The imaging device 16 images, under an observation environment in which an electron microscope or the like is used, the resist film R patterned on the wafer W (step S16) and sends an image of an actual pattern of the resist film R to the pattern-correction supporting apparatus 17. When the image of the actual pattern of the resist film R is sent to the pattern-correction supporting apparatus 17, the pattern comparing unit 18a compares the actual pattern of the resist film R imaged by the imaging device 16 and the target layout pattern before the layout values are changed by the layout-value changing unit 12 (step S17).

The difference calculating unit 18b calculates differences between the dimensions of the actual pattern of the resist film R imaged by the imaging device 16 and the target layout pattern obtained from the design data created by the CAD system 11 (step S18). The correction-value selecting unit 18c selects the layout value after the change to reduce the differences between the dimensions calculated by the difference calculating unit 18b (step S19).

Consequently, even when an actual pattern at the time when the layout values of the target layout pattern are changed on the design data is formed on the wafer W, the actual pattern on the wafer W can be compared with the target layout pattern. This makes it possible to improve dimension accuracy of the actual pattern transferred onto the wafer W without increasing load applied to the OPC. Even when condition setting for a process is insufficient or when OPC accuracy is insufficient, it is possible to form an actual pattern having dimensions as designed on the wafer W.

Instead of causing the correction-value selecting unit 18c to select the layout value after the change, the pattern-correction supporting apparatus 17 can cause the display screen 19a to display the differences between the dimensions calculated by the difference calculating unit 18b in association with the layout values after the change. Then, the pattern-correction supporting apparatus 17 can allow a user to manually select the layout value after the change to minimize the differences between the dimensions calculated by the difference calculating unit 18b.

When the image of the actual pattern of the resist film R is sent to the pattern-correction supporting apparatus 17, the pattern-correction supporting apparatus 17 can cause the display screen 19a to display an image G2 of the actual pattern of the resist film R to be superimposed on an image G1 of the target layout pattern obtained from the design data created by the CAD system 11. Alternatively, the pattern-correction supporting apparatus 17 can cause the display screen 19a to display differences D between the dimensions of the actual pattern and the layout pattern.

To calculate differences between the dimensions of the actual pattern of the resist film R imaged by the imaging device 16 and the target layout pattern obtained from the design data created by the CAD system 11, a die-to-database comparing device or a die-to-die comparing device can be used.

When the layout value after the change is selected at step S19, a semiconductor device can be formed on a wafer by transferring the target layout pattern onto a semiconductor substrate using a photomask manufactured based on the design data corresponding to the selected layout value.

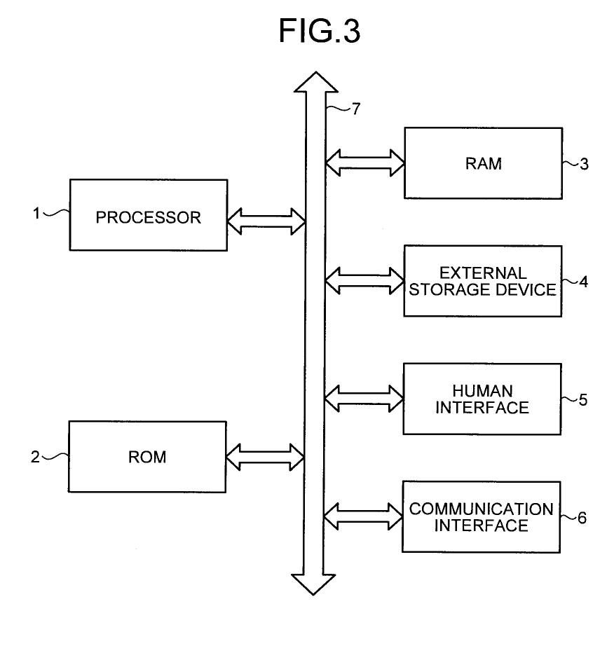

FIG. 3 is a block diagram of the hardware configuration of the pattern-correction supporting apparatus according to the first embodiment.

In FIG. 3, the pattern-correction supporting apparatus 17 shown in FIG. 1 can include a processor 1 including a central processing unit (CPU), a read only memory (ROM) 2 that stores stationary data, a random access memory (RAM) 3 that provides the processor 1 with a work area and the like, an external storage device 4 that stores a computer program for causing the processor 1 to operate and various data, a human interface 5 that mediates a person and a computer, and a communication interface 6 that provides communication means with the outside. The processor 1, the ROM 2, the RAM 3, the external storage device 4, the human interface 5, and the communication interface 6 are connected to one another via a bus 7.

As the external storage device 4, for example, magnetic disks such as a hard disk, optical disks such as a DVD, and portable semiconductor storage devices such as a USB memory and a memory card can be used. As the human interface 5, for example, a keyboard and a mouse can be used as an input interface and a display and a printer can be used as an output interface. As the communication interface 6, for example, a LAN card, a modem, and a router for connection to the Internet, a LAN, and the like can be used.

The processor 1 can realize functions executed in the pattern comparing unit 18a, the difference calculating unit 18b, and the correction-value selecting unit 18c of the pattern-correction supporting apparatus 17 shown in FIG. 1 by executing a pattern-correction supporting program. A computer program that the pattern-correction supporting apparatus 17 causes the processor 1 to execute can be stored in the external storage device 4 and read into the RAM 3 when the computer program is executed, can be stored in the ROM 2 in advance, or can be acquired via the communication interface 6.

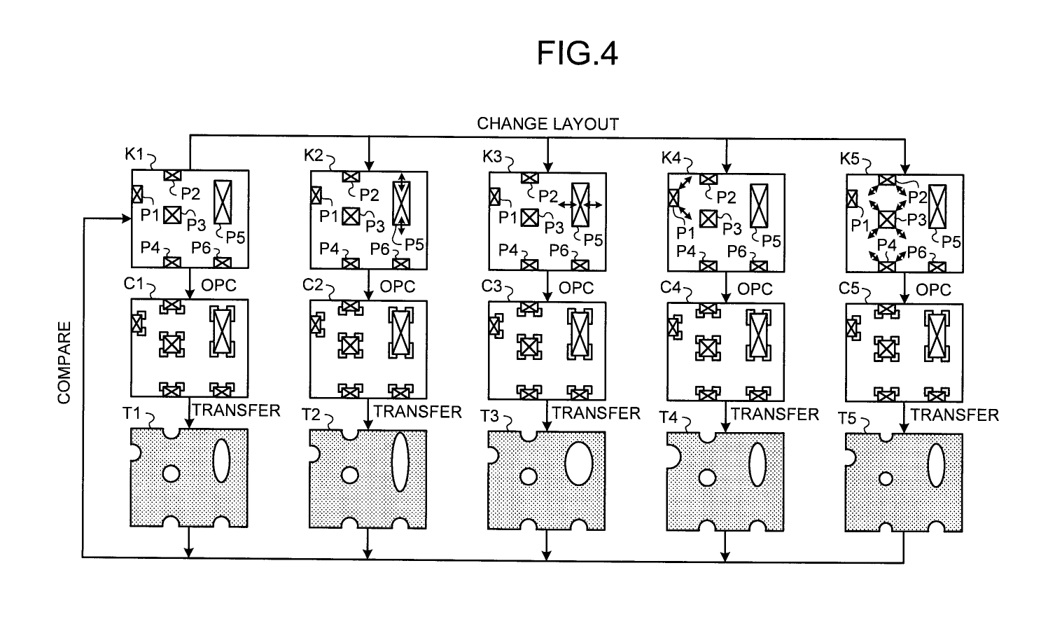

FIG. 4 is a diagram of design layout patterns used for the pattern-correction supporting method according to the first embodiment, mask patterns after OPC processing, and actual patterns transferred onto a wafer.

In FIG. 4, when a target layout pattern K1 is created on the CAD system 11, the layout-value changing unit 12 changes layout values of the layout pattern K1 on design data, whereby, for example, layout patterns K2 to K5 are generated. In the layout pattern K1, for example, contact patterns P1 to P6 are formed. In the layout pattern K2, for example, the dimension in the vertical direction of the contact pattern P5 formed in the layout pattern K1 is increased or decreased. In the layout pattern K3, for example, the dimension in the horizontal direction of the contact pattern P5 formed in the layout pattern K1 is increased or decreased. In the layout pattern K4, for example, the size of the contact pattern P1 formed in the layout pattern K1 is increased or decreased. In the layout pattern K5, for example, the sizes of the contact patterns P2 to P4 formed in the layout pattern K1 are increased or decreased.

The OPC processing unit 13 applies OPC processing to the layout patterns K1 to K5, whereby mask patterns C1 to C5 respectively corresponding to the layout patterns K1 to K5 are created.

Actual patterns T1 to T5 respectively corresponding to the layout patterns K1 to K5 are formed on the wafer W by using the photomask M on which the mask patterns C1 to C5 are formed.

The imaging device 16 images the actual patterns T1 to T5 formed on the wafer W. The pattern-correction supporting apparatus 17a compares the actual patterns T1 to T5 and the layout pattern K1. The pattern-correction supporting apparatus 17a calculates differences between the dimensions of the actual patterns T1 to T5 and the dimensions of the layout pattern K1 and selects the layout patterns K1 to K5 to minimize the differences between the dimensions of the actual patterns T1 to T5 and the dimensions of the layout patterns K1. This makes it possible to form actual patterns having dimensions closest to design dimensions on the wafer W.

The actual patterns T1 to T5 can be formed as test patterns on a TEG region of the wafer W. For example, when the layout pattern K2 is selected out of the layout patterns K1 to K5 to minimize the differences between the dimensions of the actual patterns T1 to T5 and the dimensions of the layout pattern K1, a semiconductor integrated circuit such as an SRAM is formed on the wafer W by using the layout pattern K2 instead of the layout pattern K1. This makes it possible to minimize a difference from the layout pattern K1.

In the method explained in the first embodiment, the layout-value changing unit 12 and the OPC processing unit 13 are provided separately from the pattern-correction supporting apparatus 17a. However, the layout-value changing unit 12 or the OPC processing unit 13 can be incorporated in the pattern-correction supporting apparatus 17a. Further, the pattern-correction supporting apparatus 17a can be incorporated in the CAD system 11.

In the first embodiment, the resist patterns are explained as an example of the actual patterns formed on the wafer W. However, the actual patterns can be wiring patterns, electrode patterns, and contact patterns.

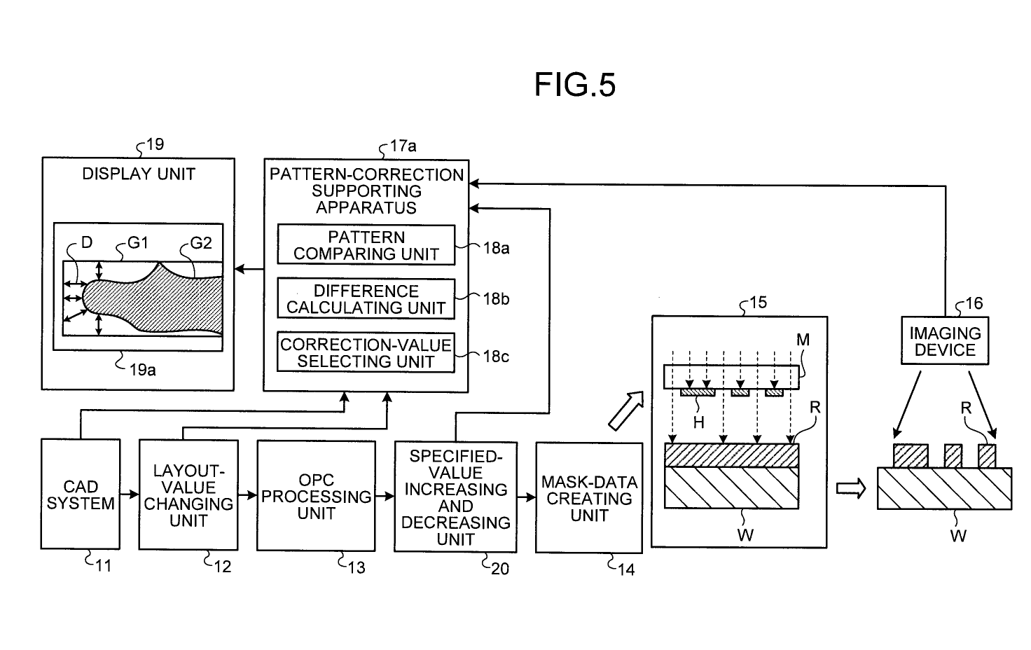

FIG. 5 is a block diagram of the schematic configuration of a system to which a pattern-correction supporting method according to a second embodiment of the present invention is applied.

In FIG. 5, this system includes a specified-value increasing and decreasing unit 20 in addition to the components shown in FIG. 1. The CAD system 11, the layout-value changing unit 12, the imaging device 16, the display device 19, and the specified-value increasing and decreasing unit 20 are connected to the pattern-correction supporting apparatus 17a. The difference calculating unit 18b can calculate differences between the dimensions of an actual pattern on the wafer W imaged by the imaging device 16 and a target layout pattern obtained from design data created by the CAD system 11. The difference calculating unit 18b can calculate fluctuation width of the differences between the dimensions of the actual pattern on the wafer at the time when a mask dimension specified value is increased or decreased and the dimensions of the target layout pattern obtained from the design data. The specified-value increasing and decreasing unit 20 can increase and decrease a mask dimension specified value of a layout pattern subjected to optical proximity correction by the OPC processing unit 13.

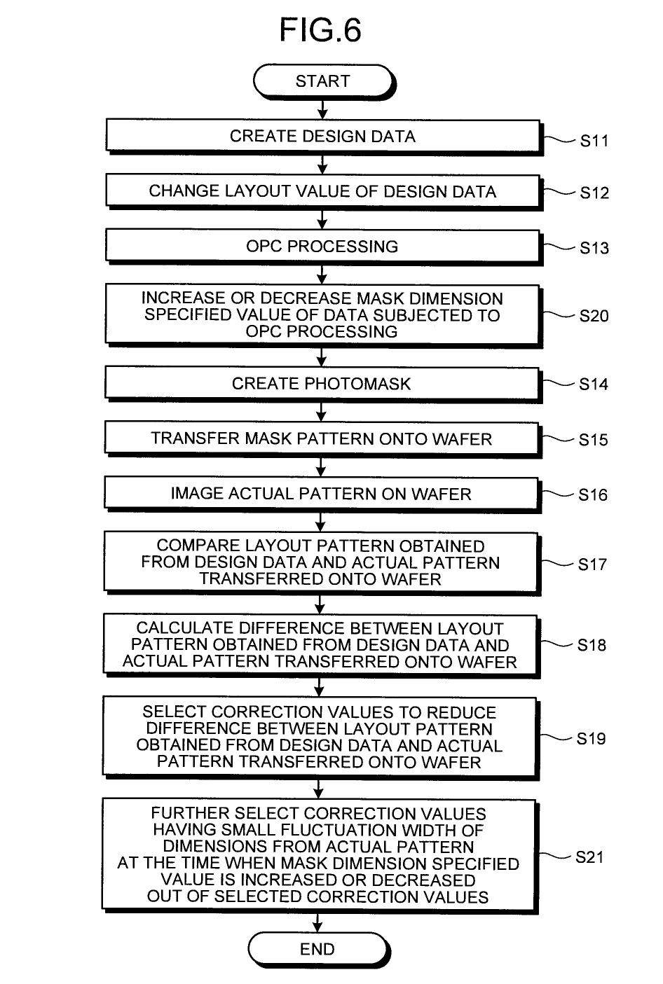

FIG. 6 is a flowchart of the pattern-correction supporting method according to the second embodiment.

In FIG. 6, processing same as the processing at steps S11 to S13 in FIG. 2 is performed to generate a layout pattern after the optical proximity correction with layout values changed on design data. The layout pattern is sent to the specified-value increasing and decreasing unit 20. The specified-value increasing and decreasing unit 20 creates a layout pattern with a mask dimension specified value (a dimension error during mask manufacturing) increased or decreased from that in the layout pattern after the optical proximity correction with the layout values changed on the design data (step S20) and sends the layout pattern to the mask-data creating unit 14.

Processing same as the processing at steps S14 to S19 in FIG. 2 is applied to the layout pattern with the mask dimension specified value increased or decreased by the specified-value increasing and decreasing unit 20, whereby an actual pattern on the wafer W and a target layout pattern obtained from the design data are compared and differences between the dimensions of the actual pattern on the wafer W and the target layout pattern obtained from the design data are calculated. The layout value after the change is selected to reduce differences between the dimensions of the actual pattern on the wafer W obtained from the layout pattern before the increase or decrease of the mask dimension specified value and the target layout pattern obtained from the design data. In the second embodiment, a plurality of layout values after the change can be selected.

The difference calculating unit 18b shown in FIG. 5 calculates fluctuation width of the differences between the dimensions of the actual pattern on the wafer W obtained from the layout pattern after the increase or decrease of the mask dimension specified value and the target layout pattern obtained from the design data. The correction-value selecting unit 18c further selects the layout values having small fluctuation width of the differences between these patterns out of the layout values selected at step S19 (step S21).

Consequently, even when an actual pattern at the time when the mask dimension specified value is increased or decreased is formed on the wafer W, the actual pattern on the wafer W can be compared with the target layout pattern. Therefore, even when there is a manufacturing error in mask dimensions, it is possible to improve dimension accuracy of the actual pattern transferred onto the wafer W without increasing load imposed to the OPC. Even when condition setting for a process is insufficient or when OPC accuracy is insufficient, it is possible to form an actual pattern having dimensions as designed on the wafer W.

In the method explained in the embodiment shown in FIG. 6, the layout values after the change are selected to reduce the differences between the dimensions of the actual pattern on the wafer W obtained from the layout pattern before the increase or decrease of the mask dimension specified value and the target layout pattern obtained from the design data. The layout values having the small fluctuation width of the differences between these patterns at the time when the mask dimension specified value is increased or decreased are further selected out of the selected layout values. However, it is also possible to select, at a time, the layout values after the change having small differences between the dimensions of the actual pattern on the wafer W obtained from the layout pattern before the increase or decrease of the mask dimension specified value and the target layout pattern obtained from the design data and having small fluctuation width of the differences between these patterns at the time when the mask dimension specified value is increased or decreased.

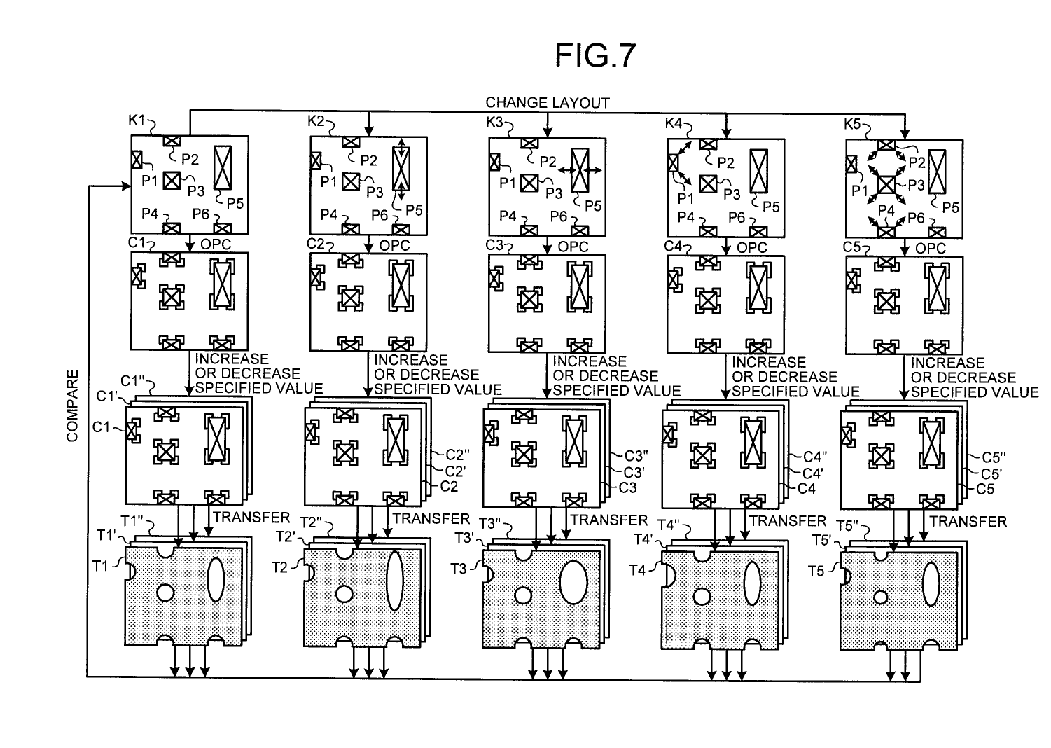

FIG. 7 is a diagram of design layout patterns used for the pattern-correction supporting method according to the second embodiment, mask patterns after OPC processing, and actual patterns transferred onto a wafer.

In FIG. 7, when a target layout pattern K1 is created on the CAD system 11, the layout-value changing unit 12 changes layout values of the layout pattern K1 on design data, whereby, for example, layout patterns K2 to K5 are generated.

The OPC processing unit 13 applies OPC processing to the layout patterns K1 to K5, whereby mask patterns C1 to C5 respectively corresponding to the layout patterns K1 to K5 are generated.

The specified-value increasing and decreasing unit 20 increases or decreases a mask dimension specified value with respect to the mask pattern C1, whereby mask patterns C1′ and C1″ are created. The specified-value increasing and decreasing unit 20 increases or decreases the mask dimension specified value with respect to the mask pattern C2, whereby mask patterns C2′ and C2″ are created. The specified-value increasing and decreasing unit 20 increases or decreases the mask dimension specified value with respect to the mask pattern C3, whereby mask patterns C3′ and C3″ are created. The specified-value increasing and decreasing unit 20 increases or decreases the mask dimension specified value with respect to the mask pattern C4, whereby mask patterns C4′ and C4″ are created. The specified-value increasing and decreasing unit 20 increases or decreases the mask dimension specified value with respect to the mask pattern C5, whereby mask patterns C5′ and C5″ are created.

Actual patterns T1 to T5, T1′ to T5′, and T1″ to T5″ are formed on the wafer W by using the photomask M on which the mask patterns C1 to C5, C1′ to C5′, and C1″ to C5″ are formed.

The imaging device 16 images the actual patterns T1 to T5, T1′ to T5′, and T1″ to T5″ formed on the wafer W. The pattern-correction supporting apparatus 17a compares the actual patterns T1 to T5, T1′ to T5′, and T1″ to T5″ and the layout pattern K1. The pattern-correction supporting apparatus 17a calculates differences between the dimensions of the actual patterns T1 to T5 and the dimensions of the layout pattern K1. The pattern-correction supporting apparatus 17a selects any ones of the layout patterns K1 to K5, for example, the layout patterns K2 and K5 to reduce the differences between the dimensions of the actual patterns T1 to T5 and the layout pattern K1.

For example, when the layout patterns K2 and K5 are selected, the pattern-correction supporting apparatus 17a compares fluctuation width of differences between the dimensions of the actual patterns T2, T2′, and T2″ corresponding to the layout pattern K2 and fluctuation width of differences between the dimensions of the actual patterns T5, T5′, and T5″ corresponding to the layout pattern K5 and the dimensions of the layout pattern K1. The pattern-correction supporting apparatus 17a further selects the layout pattern K2 or K5 having smaller fluctuation width of the differences between the dimensions of these patterns. For example, when the fluctuation width of the differences between the dimensions of the actual patterns T5, T5′, and T5″ and the dimensions of the layout pattern K1 is smaller than the fluctuation width of the differences between the dimensions of the actual patterns T2, T2′, and T2″ and the dimensions of the layout pattern K1, the pattern-correction supporting apparatus 17a selects the layout pattern K2.

The actual patterns T1 to T5, T1′ to T5′, and T1″ to T5″ can be formed as test patterns in the TEG region or the like of the wafer W. When the layout pattern K2 is selected by the processing explained above, a semiconductor integrated circuit such as an SRAM is formed on the wafer W by using the layout pattern K2 instead of the layout pattern K1. This makes it possible to reduce a difference from the layout pattern K1 while reducing the influence of a manufacturing error of a mask dimension on layout accuracy of actual patterns.

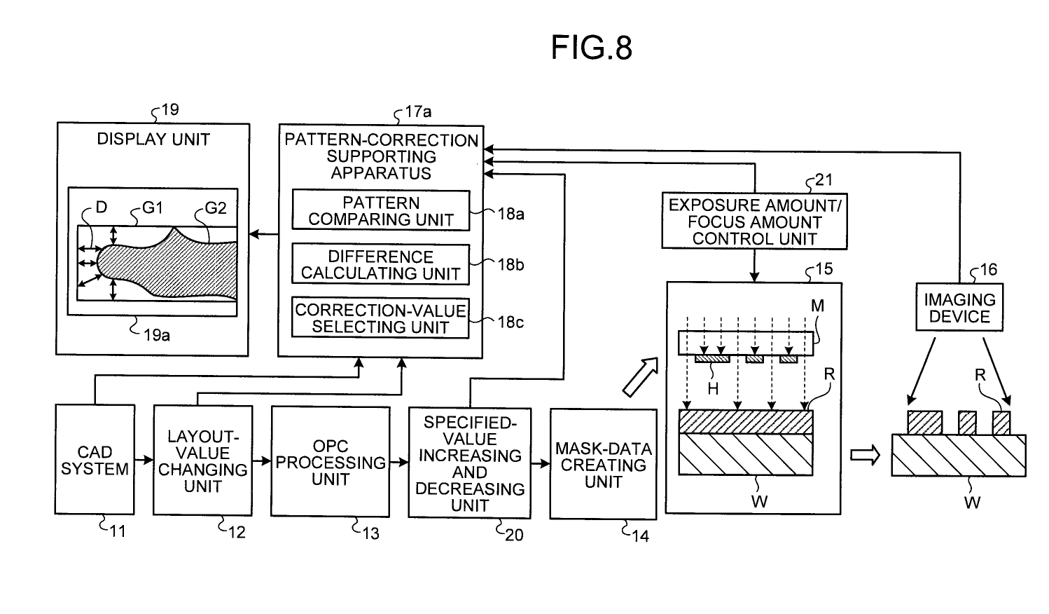

FIG. 8 is a block diagram of the schematic configuration of a system to which a pattern-correction supporting method according to a third embodiment of the present invention is applied.

In FIG. 8, this system includes an exposure amount/focus amount control unit 21 in addition to the components shown in FIG. 5. The CAD system 11, the layout-value changing unit 12, the imaging device 16, the display device 19, the specified-value increasing and decreasing unit 20, and the exposure amount/focus amount control unit 21 are connected to the pattern-correction supporting apparatus 17a. The difference calculating unit 18b can calculates differences between an actual pattern on the wafer W imaged by the imaging device 16 and a target layout pattern obtained from design data created by the CAD system 11. The difference calculating unit 18b can calculate fluctuation width of differences between the dimensions of the actual pattern on the wafer W at the time when an exposure amount and a focus amount are varied and the dimensions of the target layout pattern obtained from the design data. The exposure amount/focus amount control unit 21 can control an exposure amount and a focus amount of the exposing device 15.

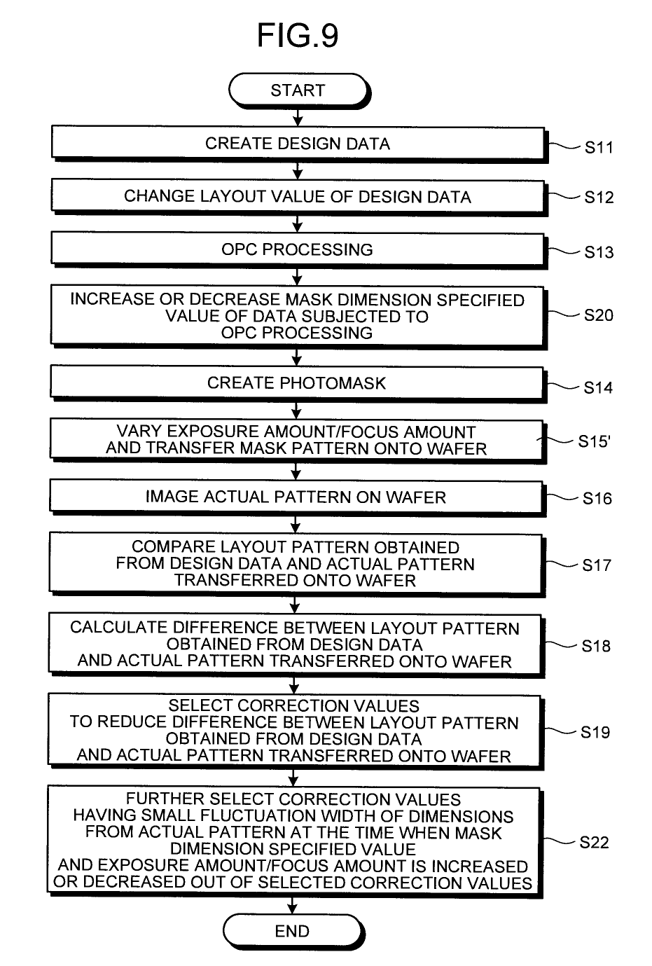

FIG. 9 is a flowchart of the pattern-correction supporting method according to the third embodiment.

In FIG. 9, processing same as the processing at steps S11 to S13 and S20 in FIG. 6 is performed to generate a layout pattern with a mask dimension specified value increased or decreased with respect to a layout pattern after the optical proximity correction with layout values changed on design data. The layout pattern is sent to the mask-data creating unit 14.

The mask-data creating unit 14 creates mask data corresponding to the layout pattern with the mask dimension specified value increased or decreased by the specified-value increasing and decreasing unit 20. The light blocking film H is formed on the photomask M based on the mask data.

Exposure of the resist film R on the wafer W is performed via the photomask M while an exposure amount and a focus amount varied by the exposure amount/focus amount control unit 21 (step S15′). Processing same as the processing at steps S16 to S19 in FIG. 5 is applied to an actual pattern formed on the wafer W while the exposure amount and the focus amount are varied, whereby the actual pattern on the wafer W and the target layout pattern obtained from the design data are compared. The layout value after the change is selected to reduce a difference between these patterns. In the third embodiment, a plurality of layout values after the change can be selected.

A mask-fluctuation-width calculating unit and a process-fluctuation-width calculating unit calculate fluctuation width of differences between the dimensions of the actual pattern on the wafer W obtained from the layout pattern at the time when the mask dimension specified value and the exposure amount/the focus amount are varied and the target layout pattern obtained from the design data. The correction-value selecting unit 18c further selects layout values having small fluctuation width of the differences between these patterns out of the layout values selected at step S19 (step S22).

Consequently, even when an actual pattern at the time when the exposure amount and the focus amount are varied is formed on the wafer W, the actual pattern can be compared with the target layout pattern. Therefore, even when process fluctuation occurs in a photolithography process, it is possible to improve dimension accuracy of the actual pattern transferred onto the wafer W without increasing load applied to the OPC. Even when condition setting for a process is insufficient or when OPC accuracy is insufficient, it is possible to form an actual pattern having dimensions as designed on the wafer W.

In the method explained in the embodiment shown in FIG. 9, the layout values after the change are selected to reduce the differences between the actual pattern on the wafer W and the target layout pattern obtained from the design data. The layout values having small fluctuation width of the differences at the time when the mask dimension specified value and the exposure amount/the focus amount are varied are further selected out of the selected layout values. However, it is also possible to select, at a time, layout values having small differences between the actual pattern on the wafer W and the target layout pattern obtained from the design data and having small fluctuation width of the differences at the time when the mask dimension specified value and the exposure amount/the focus amount are varied.

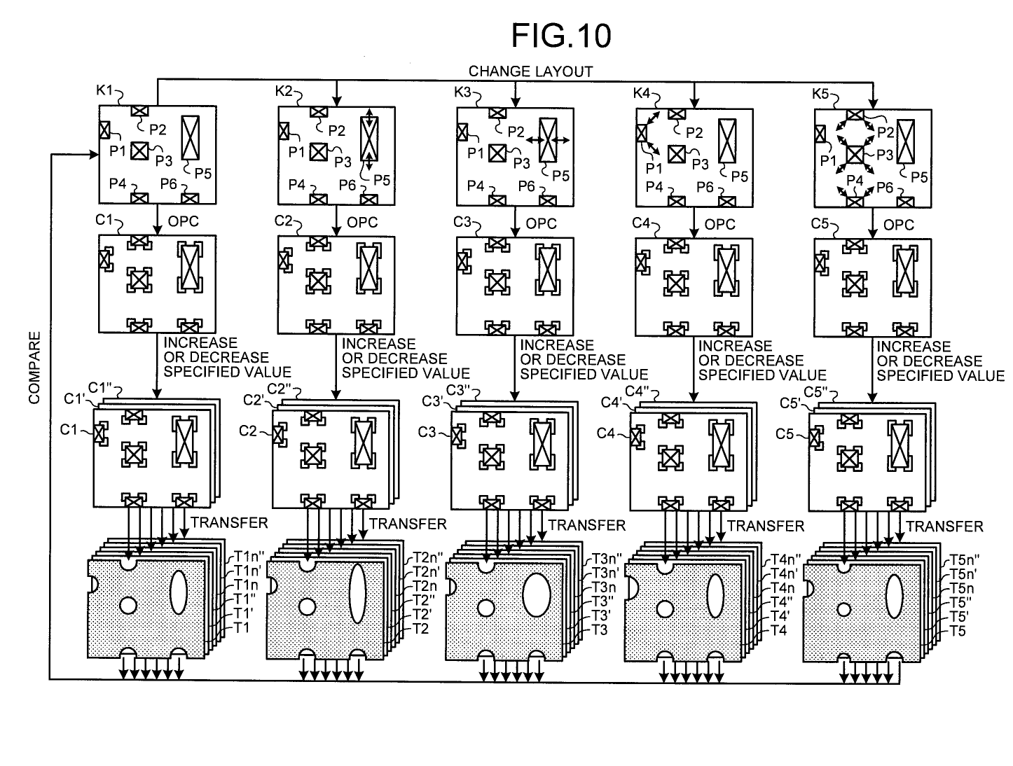

FIG. 10 is a diagram of an example of design layout pattern used for the pattern-correction supporting method according to the third embodiment, mask patterns after OPC processing, and actual patterns transferred onto a wafer.

In FIG. 10, when a target layout pattern K1 is created on the CAD system 11, the layout-value changing unit 12 changes layout values of the layout pattern K1 on design data, whereby, for example, layout patterns K2 to K5 are generated.

The OPC processing unit 13 applies OPC processing to the layout patterns K1 to K5, whereby mask patterns C1 to C5 respectively corresponding to the layout patterns K1 to K5 are generated.

The specified-value increasing and decreasing unit 20 increases or decreases a mask dimension specified value with respect to the mask patterns C1 to C5, whereby mask patterns C1′ to C5′ and C1″ to C5″ are created.

Actual patterns T1 to T5, T1′ to T5′, T1″ to T5″ are formed on the wafer W by using the photomask M on which the mask patterns C1 to C5, C1′ to C5′, and C1″ to C5″ are formed. Actual patterns T1n to T5n, T1n′ to T5n′, and T1n″ to T5n″ are formed on the wafer W by using the photomask M on which the mask patterns C1 to C5, C1′ to C5′, and C1″ to C5″ are formed and varying an exposing amount and a focus amount.

The imaging device 16 images the actual patterns T1 to T5, T1′ to T5′, T1″ to T5″, T1n to T5n, T1n′ to T5n′, and T1n″ to T5n″. The pattern-correction supporting apparatus 17a compares the actual patterns T1 to T5, T1′ to T5′, T1″ to T5″, T1n to T5n, T1n′ to T5n′, and T1n″ to T5n″ and the layout pattern K1. The pattern-correction supporting apparatus 17a calculates differences between the dimensions of the actual patterns T1 to T5 and the dimensions of the layout pattern K1. The pattern-correction supporting apparatus 17a selects any ones of the layout patterns K1 to K5, for example, the layout patterns K2, K3, and K5 to reduce the differences between the dimensions of the actual patterns T1 to T5 and the layout pattern K1.

For example, when the layout patterns K2, K3, and K5 are selected, the difference calculating unit 18b shown in FIG. 8 calculates fluctuation width of differences between the dimensions of the actual patterns T2, T2′, and T2″ corresponding to the layout pattern K2 and the dimensions of the layout patterns K1, fluctuation width of differences between the dimensions of the actual patterns T3, T3′, and T3″ corresponding to the layout pattern K3 and the dimensions of the layout pattern K1, and fluctuation width of differences between the dimensions of the actual patterns T5, T5′, and T5″ corresponding to the layout pattern K5 and the dimensions of the layout pattern K1. The pattern-correction supporting apparatus 17a compares the fluctuation widths of the differences between the dimensions of these patterns and further selects any ones of the layout patterns K2, K3, and K5 having small fluctuation widths of the differences between the dimensions of the patterns, for example, the layout patterns K2 and K5.

For example, when the layout patterns K2 and K5 are selected, the difference calculating unit 18b shown in FIG. 8 calculates fluctuation width of differences between the dimensions of the actual patterns T2 and T2n corresponding to the layout pattern K2 and the dimensions of the layout patterns K1 and fluctuation width of differences between the dimensions of the actual patterns T5 and T5n corresponding to the layout pattern K5 and the dimensions of the layout pattern K1. The pattern-correction supporting apparatus 17a compares the fluctuation widths of the differences between the dimensions of these patterns and further selects any one of the layout patterns K2 and K5 having smaller fluctuation width of the differences between the dimensions of the patterns. For example, when the fluctuation width of the differences between the dimensions of the actual patterns T5 and T5n and the dimensions of the layout pattern K1 is smaller than the fluctuation width of the differences between the dimensions of the actual patterns T2 and T2n and the dimensions of the layout pattern K1, the pattern-correction supporting apparatus 17a selects the layout pattern K2.

The actual patterns T1 to T5, T1′ to T5′, T1″ to T5″, T1n to T5n, T1n′ to T5n′, and T1n″ to T5n″ can be formed as test patterns in the TEG region or the like of the wafer W. When the layout pattern K2 is selected by the processing explained above, a semiconductor integrated circuit such as an SRAM is formed on the wafer W by using the layout pattern K2 instead of the layout pattern K1. This makes it possible to reduce a difference from the layout pattern K1 while reducing the influence of a manufacturing error of a mask dimension and process fluctuation on layout accuracy of actual patterns.

In the method explained in the third embodiment, the layout pattern with the mask dimension specified value increased or decreased is used and then the exposure amount and the focus amount are varied. However, it is also possible to vary the exposure amount and the focus amount without increasing or decreasing the mask dimension specified value.

In the method explained in the third embodiment, to take into account process fluctuation in forming actual patterns on the wafer W, the exposure amount and the focus amount are varied. However, etching conditions, film forming conditions, and the like can also be varied when actual patterns formed on the wafer W are wiring patterns, electrode patterns, contact patterns, or the like.

In changing a layout value of design data created by the CAD system 11, when a layout pattern is enormous, it is also possible to divide the layout pattern and change the layout value for each of the divided layout patterns.

In the method explained in the embodiment, the resist pattern actually formed on the wafer W is used as a pattern on wafer. However, a simulated pattern obtained by simulating actual patterns formed on the wafer W can also be used as the pattern on wafer.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A pattern-correction supporting method comprising:
creating design data corresponding to a target layout;
changing a layout value of design data corresponding to a target layout;
applying optical proximity correction to the changed design data;
forming patterns on a wafer with the photomask on which the layout pattern subjected to the optical proximity correction is formed;
comparing the pattern on wafer and the target layout pattern before the layout value is changed.

2. The pattern-correction supporting method according to claim 1, wherein the pattern on wafer is a resist pattern actually formed on the wafer.

3. The pattern-correction supporting method according to claim 1, wherein the pattern on wafer is a pattern after etching actually formed on the wafer.

4. The pattern-correction supporting method according to claim 2, wherein the pattern on wafer is formed as a test pattern in a TEG region of the wafer.

5. The pattern-correction supporting method according to claim 1, wherein the pattern on wafer is a simulated pattern obtained by simulating a resist pattern formed on the wafer.

6. The pattern-correction supporting method according to claim 1, further comprising calculating, based on a result of comparison of an image of the pattern on wafer and an image of the target layout pattern, differences between dimensions of the pattern on wafer and the target layout pattern and selecting a correction value of the design data to reduce the differences between the dimensions.

7. The pattern-correction supporting method according to claim 1, further comprising calculating, based on a result of comparison of an image of the pattern on wafer and an image of the target layout pattern, differences between dimensions of the pattern on wafer and the target layout pattern and displaying the differences between the dimensions in association with the layout value after the change.

8. The pattern-correction supporting method according to claim 1, further comprising causing a display screen to display an image of the pattern on wafer and an image of the target layout pattern thereon to be superimposed one top of the other.

9. A pattern-correction supporting method comprising:
creating design data corresponding to a target layout;
changing a layout value of the created design data;
applying optical proximity correction to the changed design data;
increasing or decreasing a mask dimension specified value of the layout pattern subjected to the optical proximity correction;
forming patterns on a wafer with the photomask on which the layout pattern after the optical proximity correction with the mask dimension specified value increased or decreased is formed;
comparing the pattern on wafer and the target layout pattern before the layout value is changed.

10. The pattern-correction supporting method according to claim 9, further comprising
selecting a plurality of layout values after the change to reduce differences between dimensions of a pattern on wafer obtained from the layout pattern before the increase or decrease of the mask dimension specified value and the target layout pattern obtained from the design data; and
further selecting layout values having small fluctuation width of differences between these patterns at the time when the mask dimension specified value is increased or decreased out of the selected layout values.

11. The pattern-correction supporting method according to claim 9, further comprising selecting layout values after the change having small differences between dimensions of the pattern on wafer obtained from the layout pattern before the increase or decrease of the mask dimension specified value and the target layout pattern obtained from the design data and having small fluctuation width of differences between these patterns at the time when the mask dimension specified value is increased or decreased.

12. The pattern-correction supporting method according to claim 9, wherein a process condition in calculating a pattern on wafer corresponding to the layout pattern is fluctuated.

13. The pattern-correction supporting method according to claim 12, further comprising:
selecting a plurality of layout values after the change to reduce differences between dimensions of a pattern on wafer obtained from the layout pattern before fluctuation of the mask dimension specified value and the process condition and the target layout pattern obtained from the design data; and
further selecting layout values having small fluctuation width of differences between these patterns at the time when the mask dimension specified value and the process condition are fluctuated out of the selected layout values.

14. The pattern-correction supporting method according to claim 12, further comprising selecting layout values after the change having small differences between dimensions of a pattern on wafer obtained from the layout pattern before fluctuation of the mask dimension specified value and the process condition and the target layout pattern obtained from the design data and having small fluctuation width of differences between these patterns at the time when the mask dimension specified value and the process condition are fluctuated.

15. A pattern-correction supporting method comprising:
preparing a first layout corresponding to a first pattern, the first pattern is being target pattern to be formed on a substrate;
changing the first layout to a second layout, the second layout is corresponding to a second pattern different from the first pattern; and
applying optical proximity correction to the second layout.

16. A method of manufacturing a semiconductor device comprising:
changing a layout value of design data corresponding to a target layout;
applying optical proximity correction to the changed design data;
forming patterns on a wafer with the photomask on which the layout pattern subjected to the optical proximity correction is formed;
comparing the pattern on wafer and the target layout pattern before the layout value is changed;
extracting the changed design data, a result of the comparison of which satisfies a desired condition; and
transferring, onto a semiconductor substrate, a mask pattern obtained by applying the optical proximity correction to the extracted design data.

17. The method of manufacturing a semiconductor device according to claim 16, wherein the pattern on wafer is a resist pattern actually formed on the wafer.

18. The pattern-correction supporting method according to claim 16, wherein the pattern on wafer is a pattern after etching actually formed on the wafer.

19. The method of manufacturing a semiconductor device according to claim 17, wherein the pattern on wafer is formed as a test pattern in a TEG region of the wafer.

20. The method of manufacturing a semiconductor device according to claim 18, wherein the pattern on wafer is a simulated pattern obtained by simulating a resist pattern formed on the wafer.

21. The method of manufacturing a semiconductor device according to claim 16, wherein a mask dimension specified value in calculating a pattern on wafer corresponding to the layout pattern is fluctuated.

22. The method of manufacturing a semiconductor device according to claim 16, wherein a process condition in calculating a pattern on wafer corresponding to the layout pattern is fluctuated.

23. A pattern-correction supporting program for causing a computer to execute:
acquiring design data corresponding to a target layout pattern;
acquiring a layout value after change of the acquired design data; and
comparing a pattern formed by using a photomask manufactured based on the design data after the change and an image of the target layout pattern obtained from the design data.

24. A pattern-correction supporting program for causing a computer to execute:
preparing a first layout corresponding to a first pattern, the first pattern is being target pattern to be formed on a substrate;
changing the first layout to a second layout, the second layout is corresponding to a second pattern different from the first pattern; and
applying optical proximity correction to the second layout.
